(19) United States
(12) Patent Application Publication
(10) Pub. No.: US 2011/0140117 A1
(43) Pub. Date: Jun. 16, 2011

(54) DISPLAY SUBSTRATE AND METHOD OF MANUFACTURING THE SAME

(75) Inventors: Mi-Ae LEE, Cheonan-si (KR); Yeo-Geon YOON, Seoul (KR); Myung-Koo HUR, Asan-si (KR)

(73) Assignee: SAMSUNG ELECTRONICS CO., LTD., Suwon-si (KR)

(21) Appl. No.: 12/956,706

(22) Filed: Nov. 30, 2010

(30) Foreign Application Priority Data
Dec. 15, 2009 (KR) 2009-124772

(51) Int. Cl. H01L 51/52; H01L 51/56

(52) U.S. Cl. 257/59; 438/34; 257/E51.018

(57) ABSTRACT

A display substrate includes a base substrate, a signal line, a pad electrode, an organic layer, and a conductive member. The signal line is formed in a display area of the display substrate. The pad electrode extends from the signal line in a peripheral area of the display substrate. The organic layer is formed on the base substrate on which the signal line and the pad electrode are formed with a contact hole formed in correspondence with the pad electrode. The contact hole exposes a portion of the pad electrode. The conductive member includes conductive balls disposed in the contact hole and electrically connects the pad electrode with a connection terminal of a driving part providing a driving signal with the signal lines.

### CROSS REFERENCE TO RELATED APPLICATION

This application claims priority from and the benefit of Korean Patent Application No. 2009-124772, filed on Dec. 15, 2009, which is hereby incorporated by reference for all purposes as if fully set forth herein.

### BACKGROUND OF THE INVENTION

1. Field of the Invention

Exemplary embodiments of the present invention relate to a display substrate and a method of manufacturing the display substrate. More particularly, exemplary embodiments of the present invention relate to a display substrate and a method of manufacturing the display substrate that may prevent press defects from being generated at a peripheral area thereof.

2. Discussion of the Background

Generally, a display device includes a display area displaying an image and a peripheral area surrounding the display area.

A plurality of gate lines, a plurality of data lines formed on a layer different from the gate line, a switching element electrically connected to a gate line and a data line, and a pixel electrode electrically connected to the switching element, among other elements, are arranged in the display area.

A plurality of gate pad parts and a plurality of data pad parts are formed on the peripheral area. The gate pad parts connect the gate lines to a gate driving part, and the data pad parts connect the data lines to a data driving part.

Recently, a display device in which a black matrix pattern and a storage line pattern are formed has been developed. A negative organic layer is used in manufacture of the display device to increase its transmittance and production.

When the display device includes a negative-type organic film as an anisotropic conductive film in its peripheral area, a stepped portion is generated at the peripheral area so that a connection terminal of a pad electrode may become disconnected from a tape carrier package (“TCP”).

For example, in a structure excluding an organic film, a thickness difference between an upper surface of an exposed pad electrode and an insulation layer of the pad electrode may occur. However, in a structure that includes the organic film, a thickness between an upper surface of the exposed pad electrode and an insulation layer of the pad electrode and a thickness of the organic film may be different. Here, when the thickness difference is less than the diameter of a conductive ball disposed in a contact hole, a deformation of the conductive ball may not occur resulting in the pad electrode not being electrically connected to the TCP. Moreover, when the conductive ball is pressed at a boundary of the organic film, press defects may be generated at the pad electrode.

To resolve these issues, a method has been developed that produces the organic film at the peripheral area to be thinner than the thickness of the organic film in the display area.

However, when the amount of exposed organic film is decreased to reduce the thickness of the organic film at the peripheral area, an adhesive force between the organic film and the pad electrode decreases, which might produce lifting of the organic film.

### SUMMARY OF THE INVENTION

Exemplary embodiments of the present invention provide a display substrate that may prevent press defects of pad electrodes in a peripheral area of the display.

Exemplary embodiments of the present invention also provide a method of manufacturing the above-mentioned display substrate.

Additional features of the invention will be set forth in the description which follows and, in part, will be apparent from the description or may be learned by practice of the invention.

An exemplary embodiment of the present invention discloses a display substrate that comprises a base substrate comprising a display area and a peripheral area surrounding the display area; a signal line disposed on the display area; a pad electrode extending from the signal line and disposed on the peripheral area; an organic layer disposed on the base substrate on which the signal line and the pad electrode are both disposed, the organic layer comprising a contact hole corresponding with the pad electrode and exposing a portion of the pad electrode; and a conductive member comprising a plurality of conductive balls disposed within the contact hole and electrically connecting the pad electrode and a connection terminal of a driving part, the driving part to provide a driving signal to the signal lines.

An exemplary embodiment of the present invention also discloses a method of manufacturing a display substrate. The method comprises forming a signal line on a display area of a base substrate and a pad electrode extending from the signal line on a peripheral area surrounding the display area; forming an organic layer on the base substrate; removing a portion of the organic layer corresponding to the pad electrode to form a contact hole; and forming a conductive member by dispensing a conductive material comprising conductive balls within the contact hole. The conductive member electrically connects the pad electrode with a driving part providing the signal line with a driving signal.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a plan view of a display panel according to an exemplary embodiment of the present invention.

FIG. 2 is an enlarged view of portion “A” of FIG. 1.

FIG. 3 is a cross-sectional view taken along line I-I′ of FIG. 2.

FIG. 4A, FIG. 4B, FIG. 4C, FIG. 4D, FIG. 4E, FIG. 4F, and FIG. 4G are cross-sectional views of the display substrate of FIG. 3 during various stages of its manufacture.

FIG. 5 is a cross-sectional view of a display panel according to another exemplary embodiment of the present invention.

FIG. 6A, FIG. 6B, FIG. 6C, FIG. 6D, FIG. 6E, FIG. 6F, and FIG. 6G are cross-sectional views of the display substrate of FIG. 5 during various stages of its manufacture.

FIG. 7 is a cross-sectional view of a display panel according to another exemplary embodiment of the present invention.

FIG. 8A, FIG. 8B, FIG. 8C, FIG. 8D, FIG. 8E, FIG. 8F, FIG. 8G, and FIG. 8H are cross-sectional views of the display substrate of FIG. 7 during various stages of its manufacture.

### DETAILED DESCRIPTION OF THE ILLUSTRATED EMBODIMENTS

The invention is described more fully hereinafter with reference to the accompanying drawings in which embodiments of the invention are shown. This invention may, however, be embodied in many different forms and should not be construed as limited to the embodiments set forth herein. Rather, these embodiments are provided so that this disclosure is thorough and will fully convey the scope of the invention to those skilled in the art. In the drawings, the size and relative sizes of layers and regions may be exaggerated for clarity. Like reference numerals in the drawings denote like elements.

It will be understood that when an element or layer is referred to as being “on,” “connected to,” or “coupled to” another element or layer, it can be directly on, directly connected to, directly coupled to the other element or layer, or intervening elements or layers may be present. In contrast, when an element is referred to as being “directly on,” “directly connected to,” or “directly coupled to” another element or layer, there are no intervening elements or layers present.

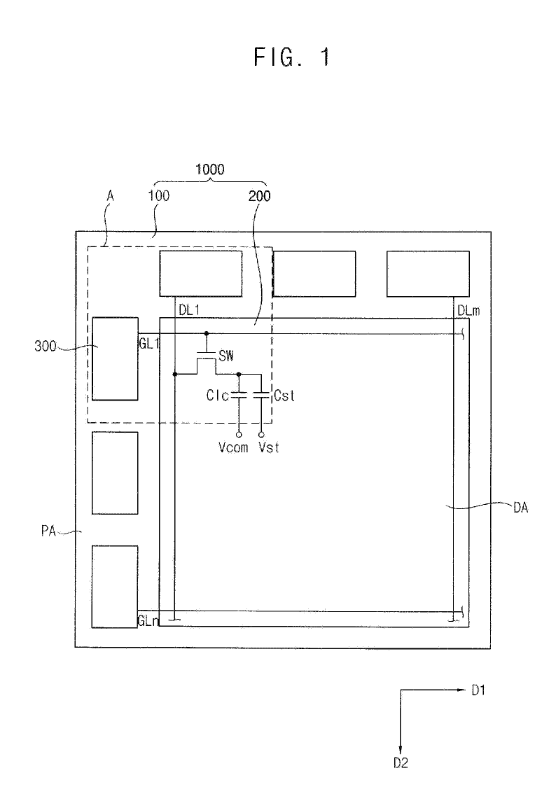

FIG. 1 is a plan of a display panel 1000 according to an exemplary embodiment of the present invention.

Referring to FIG. 1, the display panel 1000 includes a first display substrate 100, a second display substrate 200, and a liquid crystal layer (not shown) interposed between the first and second display substrates 100 and 200.

The display panel 1000 includes a display area DA, which displays an image in accordance with an arrangement of liquid crystal molecules included in the liquid crystal layer, and a peripheral area PA surrounding the display area DA. A plurality of signal lines is formed on the display area DA. The signal lines include a plurality of gate lines GL arranged in a first direction D1 and a plurality of data lines DL arranged in a second direction D2 and crossing the first direction D1.

The first display substrate 100 includes, e.g., a switching element SW electrically connected to a gate line GL and a data line DL, a storage capacitor Cst electrically connected to the switching element SW, and a liquid crystal capacitor Clc electrically connected to the switching element SW. The switching element SW, the storage capacitor Cst, and the liquid crystal capacitor Clc may be arranged in a pixel area.

A driving part 300 for providing signals provided from an external device to the display area DA is disposed on the peripheral area PA of the first substrate 100. The driving part 300 includes a gate driving part, which provides the gate lines GL with a gate driving signal, and a data driving part, which provides the data lines DL with a data driving signal. According to an exemplary embodiment, the driving part 300 may be configured in a chip configuration. According to another exemplary embodiment, the driving part 300 may be configured in a flexible printed circuit board (“FPCB”). The FPCB may include a tape carrier package (“TCP”). The TCP may include a first terminal electrically connected to an external printed circuit board (“PCB”) and a second terminal electrically connected to the first display substrate 100.

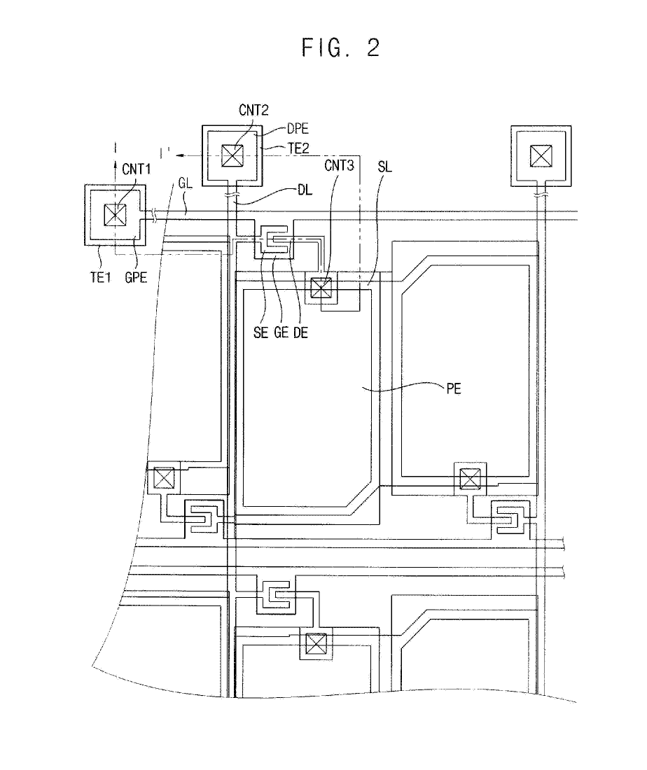

FIG. 2 is an enlarged plan view of portion “A” of FIG. 1.

Referring to FIG. 1 and FIG. 2, the first display substrate 100 includes a gate line GL, a data line DL, a pad electrode, a switching element SW, and a pixel electrode PE.

The gate line GL is formed in a first direction D1. The data line DL is formed in a second direction D2 crossing the first direction D1.

The pad electrode includes a gate pad electrode GPE extending from the gate line GL and a data pad electrode DPE extending from the data line DL. The gate pad electrode GPE is exposed by a first contact hole CNT1 formed through an organic layer (not shown) and is electrically connected to the driving part 300 through a plurality of conductive balls (not shown).

The data pad electrode DPE is exposed by a second contact hole CNT2 formed through an organic layer (not shown) and is electrically connected to the driving part 300 through conductive balls (not shown).

The switching element SW includes a gate electrode GE extending from the gate line GL, a source electrode SE extending from the data line DL, and a drain electrode DE spaced apart from the source electrode SE. The drain electrode DE electrically connects to the pixel electrode PE through a third contact hole CNT3.

In the present exemplary embodiment, the first display substrate 100 may further include a first transparent electrode TE1, a second transparent electrode TE2, and a storage line SL.

The first transparent electrode TE1 is disposed on the gate pad electrode GPE and electrically connects to the gate pad electrode GPE through a first contact hole CNT1.

The second transparent electrode TE2 is disposed on the data pad electrode DPE and electrically connects to the data pad electrode DPE through the second contact hole CNT2.

The storage line SL is formed along an edge portion of the pixel electrode PE. The storage line SL overlaps with the pixel electrode PE, as viewed in a plan view, to form the storage capacitor Cst.

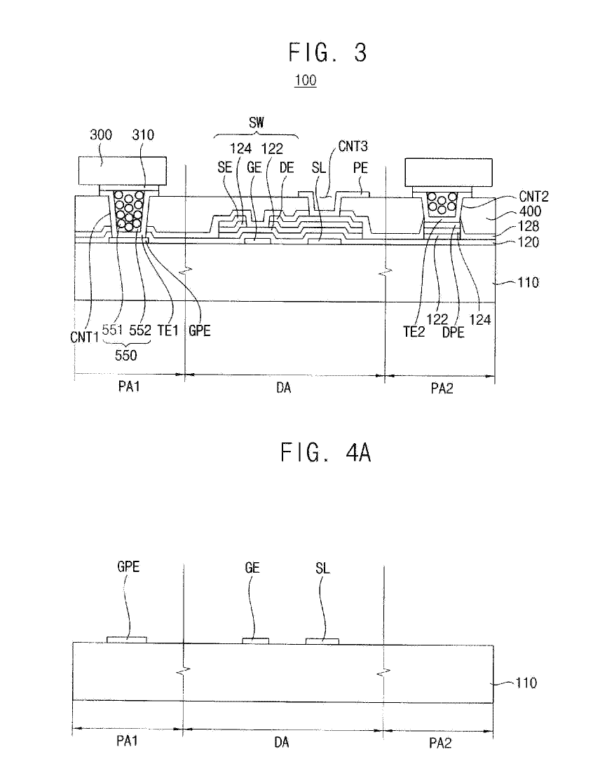

FIG. 3 is a cross-sectional view taken along line I-I′ of FIG. 2.

Referring to FIG. 2 and FIG. 3, a base substrate 110 of the first display substrate 100 includes a first peripheral area PA1, a display area DA, and a second peripheral area PA2.

A gate electrode GE, a storage line SL, a first insulation layer 120, a semiconductor layer 122, an ohmic contact layer 124, a source electrode SE, a drain electrode DE, a second insulation layer 128, an organic layer 400, and a pixel electrode PE are formed on the display area DA.

A gate pad electrode GPE, the first insulation layer 120, the second insulation layer 128, the organic layer 400, and a conductive member 550 are formed on the first peripheral area PA1. A first transparent electrode TE1 may be further formed on the first peripheral area PA1.

A data pad electrode DPE, the first insulation layer 120, the second insulation layer 128, the organic layer 400, and the conductive member 550 may be formed on the second peripheral area PA2. A second transparent electrode TE2 may be further formed on the second peripheral area PA2.

An organic layer 400 may be formed on the base substrate 110 on which the second insulation layer 128 may be formed. That is, the organic layer 400 is formed on the display area DA and the first and second peripheral areas PA1 and PA2. The organic layer 400 may include at least one of an organic film, a color filter, and a black matrix. The organic film may be a negative-type organic film to enhance transmittance of the display panel 1000. Since a profile of the negative-type organic film may be greater than a profile of a positive-type organic film, a size of the first and second contact holes CNT1 and CNT2 may be small. Thus, the negative-type organic film may enhance the aperture ratio of a display substrate.

A first contact hole CNT1, a second contact hole CNT2, and a third contact hole CNT3 may be formed through the organic layer 400 and second insulation layer 128. Thus, the organic layer 400 may include a first portion where the first and second contact holes CNT1 and CNT2 are formed and a second portion where the first and second contact holes CNT1 and CNT2 are not formed. The first portion corresponds to the gate pad electrode GPE, the data pad electrode DPE, and the second portion corresponds to the remaining portion that includes the drain electrode DE.

The negative-type organic film of the organic layer 400 is described now. In the production of the display panel, light does not irradiate the first portion, and the organic film does not harden but is removed by a developing solution. Since light irradiates the second portion, the organic film is hardened through polymerization and remains on the base substrate 110 during development. As the amount of irradiation of the second portion increases, an adhesive coupling force to the base substrate 110 increases, and the organic layer 400 may not easily lift from the base substrate 110.

According to the exposure, the first contact hole CNT1 exposes the gate pad electrode GPE, and the second contact hole CNT2 exposes the data pad electrode DPE. Further, the third contact hole CNT3 exposes the drain electrode DE.

Moreover, the first and second transparent electrodes TE1 and TE2 are disposed in correspondence with the first and second contact holes CNT1 and CNT2 of the organic layer 400, respectively. The first transparent electrode TE1 disposed in the first contact hole CN1 electrically connects to the gate pad electrode GPE. The second transparent electrode TE2 disposed in the second contact hole CN2 electrically connects to the data pad electrode DPE. The pixel electrode PE disposed in the third contact hole CNT3 electrically connects to the drain electrode DE.

The conductive member 550 includes a mix of a plurality of conductive balls 551 and an adhesive 552. The conductive member 550 is disposed within the first contact hole CNT1 and electrically connects the gate pad electrode GPE with a connection terminal 310 of the driving part 300. In this case, the driving part 300 provides a driving signal of an external device to the conductive member 550.

The conductive member 550 may be disposed within the first and second contact holes CNT1 and CNT2 by an inkjet printer. The organic layer 400 surrounds the first contact hole CNT1 and the second contact hole CNT2. In this case, the organic layer 400 may partition the first contact holes CNT1 adjacent to each other and may partition the second contact holes CNT2 adjacent to each other. Thus, when the conductive member 550 is disposed within the first contact hole CNT1 and the second contact hole CNT2, the organic layer 400 may prevent the conductive member 550 from moving outward from the area of the gate pad electrode GPE or data pad electrode DPE. Moreover, the organic layer 400 may prevent the gate pad electrode GPE from exposure to irradiation and erosion.

Moreover, a partition may be formed from a material such as the organic film of the organic layer 400, a color filter, a black matrix, and a column spacer.

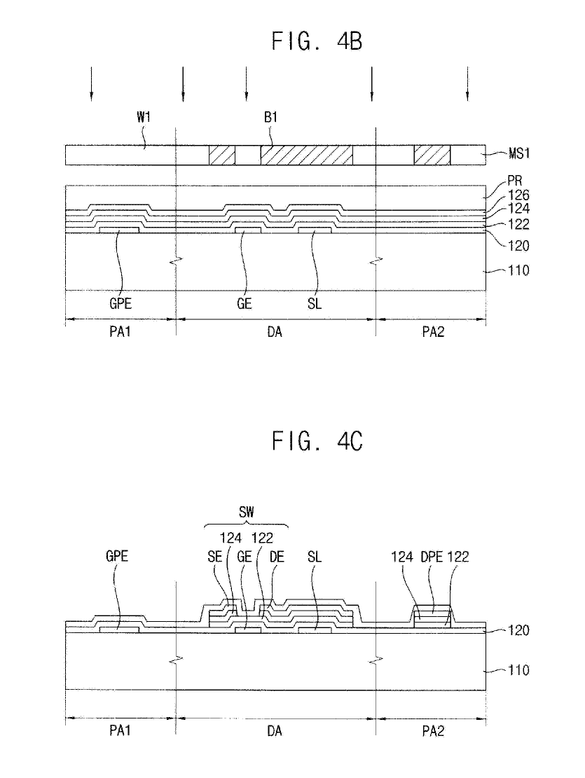

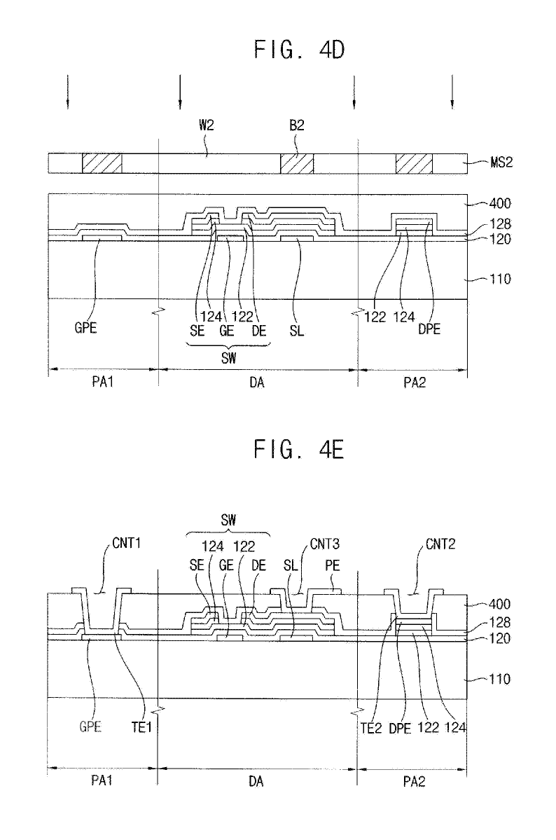

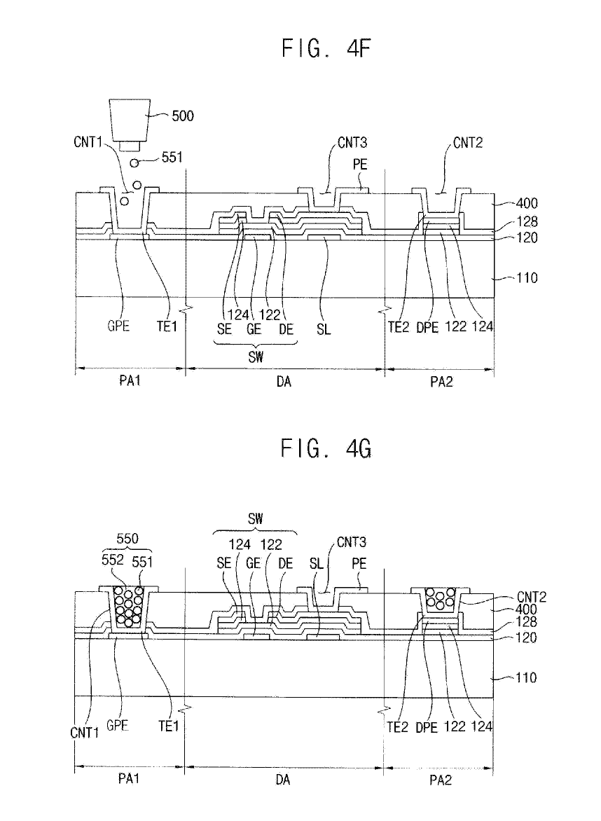

FIG. 4A, FIG. 4B, FIG. 4C, FIG. 4D, FIG. 4E, FIG. 4F, and FIG. 4G are cross-sectional views of the display substrate of FIG. 3 during various stages of its manufacture.

Referring to FIG. 2 and FIG. 4A, a gate metal layer is formed on the base substrate 110. The gate metal layer is patterned to form a gate pattern. Thus, a gate line GL, a gate electrode GE, and a storage line SL are formed on the display area DA, and a gate pad electrode GPE is formed on the first peripheral area PA1. The gate line GL, the gate electrode GE, the storage line SL, and the gate pad electrode GPE may be formed as layers identical to each other.

Referring to FIG. 2 and FIG. 4B, the first insulation layer 120, the semiconductor layer 122, the ohmic contact layer 124, and a source metal layer 126 are sequentially formed on the base substrate 110 on which the gate pattern is formed. The first insulation layer 120 may include a silicon oxide (SiOx), a silicon nitride (SiNx), or other suitable insulation layers. The semiconductor layer 122 may include amorphous silicon. The ohmic contact layer 124 may include amorphous silicon doped with N-type dopants that may occur in high concentration.

A photoresist layer PR is subsequently formed on the base substrate 110 on which the source metal layer 126 is formed. A first mask MS1 on which a photoresist pattern is formed is disposed on the base substrate 110 on which the photoresist layer is formed, and then light irradiates an upper portion of the first mask MS1. Then, the base substrate 110 is developed to form the photoresist pattern. For example, the photoresist layer may be a positive-type photoresist in which an exposed area is removed by a developing solution, and a light-blocked area is hardened to remain on the base substrate 110. Alternatively, the photoresist layer may include a negative photoresist in which a light-blocked area is removed by a developing solution, and an exposed area is hardened to remain on the base substrate 110. When the photoresist layer is a positive-type photoresist, the first mask MS1 may include a light-blocking portion B1 and a light-transmitting portion W1. In the first mask MS1, the light-blocking portion B1 is formed on a drain electrode area where the drain electrode DE will be formed, a source electrode area where the source electrode SE will be formed, and a data pad electrode area where the data pad electrode DPE will be formed. The light-transmitting portion W1 is formed on a remaining area except the light-blocking portion B1 of the first mask MS1.

Referring to FIG. 2 and FIG. 4C, a second insulation layer 128 is formed on the base substrate 110 on which the drain electrode DE, the source electrode SE, and the data pad electrode DPE are formed.

As shown in FIG. 4D, a second mask MS2 may be disposed on the base substrate 110 on which the organic layer 400 is formed. Then, light irradiates the second mask MS2, and the base substrate 110 is developed to form plural contact holes CNT1, CNT2, and CNT3 (FIG. 4E). Since the organic film included in the organic layer 400 is a negative-type, a portion where light irradiates polymerizes and hardens to remain on the base substrate 110, and a portion where light does not irradiate is removed by a developing solution. Here, the second mask MS2 may include a light-blocking portion B2 and a light-transmitting portion W2. In the second mask MS2, the light-blocking portion B2 is formed on a gate pad electrode area where the gate electrode GPE is formed, a data pad electrode area where the data pad electrode DPE is formed, and a drain electrode area where the drain electrode DE is formed. In the second mask MS2, the light-transmitting portion W2 is formed on a remaining area except the light-blocking portion B2. Thus, a first portion corresponding to the gate pad electrode area, a portion of the drain electrode, and the data pad electrode area are removed so that a first contact hole CNT1 exposing a portion of the gate pad electrode GPE, a second contact hole CNT2 exposing a portion of the data pad electrode DPE, and a third contact hole CNT3 exposing a portion of the drain electrode DE may be formed through the organic layer 400 and the second insulation layer 128, as shown in FIG. 4E.

The organic layer 400 may include at least one of an organic film, a color filter, and a black matrix. In the present exemplary embodiment, the organic layer 400 may be an organic film. The organic film may be a negative-type organic film.

Referring to FIG. 3 and FIG. 4E, a transparent electrode layer (not shown) may be formed on the base substrate 110 having the first to third contact holes CNT1, CNT2, and CNT3.

The transparent electrode layer is patterned to form a first transparent electrode TE1 corresponding to the gate pad electrode GPE, a second transparent electrode TE2 corresponding to the data pad electrode DPE, and a pixel electrode PE corresponding to a portion of the drain electrode DE. The first transparent electrode TE1 is formed on an interior surface of the first contact hole CNT1 formed through the organic layer 400 and second insulation layer 128 and is formed along an upper surface of the gate pad electrode GPE. The second transparent electrode TE2 is formed on an interior surface of the second contact hole CNT2 formed through the organic layer 400 and the second insulation layer 128 and is formed along an upper surface of the data pad electrode DPE. The pixel electrode PE is formed on an interior surface of the third contact hole CNT3 formed through the organic layer 400 and the second insulation layer 128 and is formed along an upper surface of the drain electrode DE.

In the present exemplary embodiment, the first transparent electrode TE1 is formed in correspondence with the gate pad electrode GPE, and the second transparent electrode TE2 is formed in correspondence with the data pad electrode DPE. Alternatively, the first and second transparent electrodes TE1 and TE2 may be omitted. That is, when a transparent electrode layer is formed on the base substrate 110, the transparent electrode may not be formed on the peripheral area PA, and the transparent electrode layer may be formed only on the display area DA. Thus, the first and second transparent electrodes TE1 and TE2 may be omitted.

Referring to FIG. 3, FIG. 4F, and FIG. 4G, an inkjet printer 500 may be disposed on the base substrate 110 on which the pixel electrode PE is formed or the base substrate 110 on which the first and second transparent electrodes TE1 and TE2 and the pixel electrode PE are formed. The inkjet printer 500 is disposed in a position corresponding to the first and second contact holes CNT1 and CNT2 so that the inkjet printer 500 may dispense the conductive member 550 within the first and second contact holes CNT1 and CNT2. Moreover, the inkjet printer 500 may dispense the conductive member 550 by adjusting an amount of the conductive member 550 in accordance with a depth and a size of the first and second contact holes CNT1 and CNT2. The conductive member 550 may include a plurality of conductive balls 551 for electrically connecting the gate pad electrode GPE to a connection terminal 310 of a driving part 300 and an adhesive 552 for attaching the driving part 300 onto the first display substrate 100.

Accordingly, as shown in FIG. 3, the driving part 300 is disposed on the base substrate 110 on which the conductive member 550 is dispensed. The connection terminal 310 of the driving part 300 contacts the conductive member 550.

Then, the conductive member 550 is pressed at a temperature ranging from about 170° C. to 200° C. to attach the driving part 300 to the first display substrate 100. Thus, the driving part 300 electrically connects to the gate pad electrode GPE to provide a gate driving signal to the gate line GL through the gate pad electrode GPE.

According to the present exemplary embodiment, the organic layer 400 formed at the peripheral area PA acts as a partition, and the conductive member 550 is disposed within the contact holes CNT1 and CNT2 corresponding to the pad electrodes GPE and DPE by using the inkjet printer. In this way, the organic layer 400 may prevent the conductive member 550 from flowing out of the gate pad electrode GPE or the data pad electrode DPE areas. Moreover, the organic layer 400 may prevent the gate pad electrode GPE or the data pad electrode DPE from exposure and subsequent erosion.

Moreover, removing the organic layer 400 from the peripheral area PA is not required so manufacturing of the display panel may be simplified.

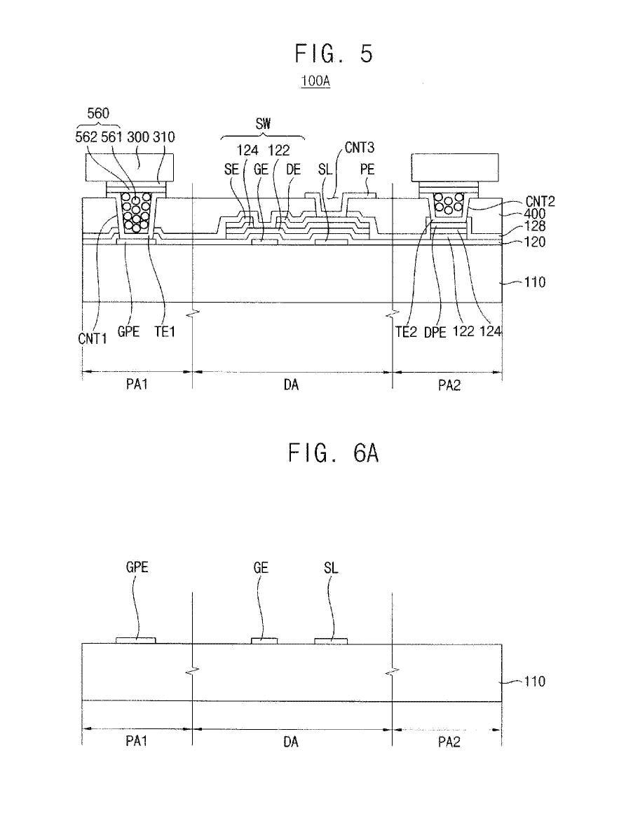

FIG. 5 is a cross-sectional view of a display panel according to another exemplary embodiment of the present invention.

The first display substrate 100A according to the present exemplary embodiment is substantially similar to the first display substrate 100 of FIG. 1 except for formation of the conductive member. Elements similar to those shown in FIG. 5 have been labeled with the same reference characters as used above to describe the exemplary embodiment of the display substrate 1000 in FIG. 1 so descriptions are simplified or not repeated.

Referring to FIG. 2 and FIG. 5, the first display substrate 100A includes a base substrate 110, an organic layer 400 and the second insulation layer 128 formed on the base substrate 110, a first contact hole CNT1 formed through the organic layer 400 and the second insulation layer 128, a second contact hole CNT2 formed through the organic layer 400 and the second insulation layer 128, a third contact hole CNT3 formed through the organic layer 400 and the second insulation layer 128, a pixel electrode PE, and a conductive member 560. The first display substrate 100A may further include a first transparent electrode TE1 and a second transparent electrode TE2.

The first contact hole CNT1 is formed through the organic layer 400 and the is second insulation layer 128 corresponding to a first peripheral area PA1 of the base substrate 110 in correspondence with an area where a gate pad electrode GPE is formed. The second contact hole CNT2 is formed through the organic layer 400 and the second insulation layer 128 corresponding to a second peripheral area PA2 of the base substrate 110 in correspondence with an area where a data pad electrode DPE is formed. The third contact hole CNT3 is formed through the organic layer 400 and the second insulation layer 128 corresponding to a portion of a drain electrode DE in correspondence with the display area DA.

The first transparent electrode TE1 is formed on an interior surface of the first contact hole CNT1 and along an upper surface of the gate pad electrode GPE to electrically connect to the gate pad electrode GPE. The second transparent electrode TE2 is formed on an interior surface of the second contact hole CNT2 and along an upper surface of the data pad electrode DPE to electrically connect to the data pad electrode DPE. The pixel electrode PE is formed on an interior surface of the third contact hole CNT3 and along an upper surface of a portion of the drain electrode DE to electrically connect to the drain electrode DE.

The conductive member 560 includes a plurality of conductive balls 561 and an adhesive film 562. The conductive balls 561 are disposed in the first and second contact holes CNT1 and CNT2. An inkjet printer 500 is located in correspondence with a position of the first and second contact holes CN1 and CNT2 and dispenses the conductive balls 561 in the first and second contact holes CNT1 and CNT2. The adhesive film 562 may be disposed on the conductive balls 561 disposed in the first and second contact holes CN1 and CNT2. Thus, the gate and data pad electrodes GPE and DPE electrically connect to the driving part 300 through the conductive balls 561, and the driving part 300 adheres to the organic layer 400 of the first display substrate 100A or the first and second transparent electrodes TE1 and TE2 through the adhesive film 562.

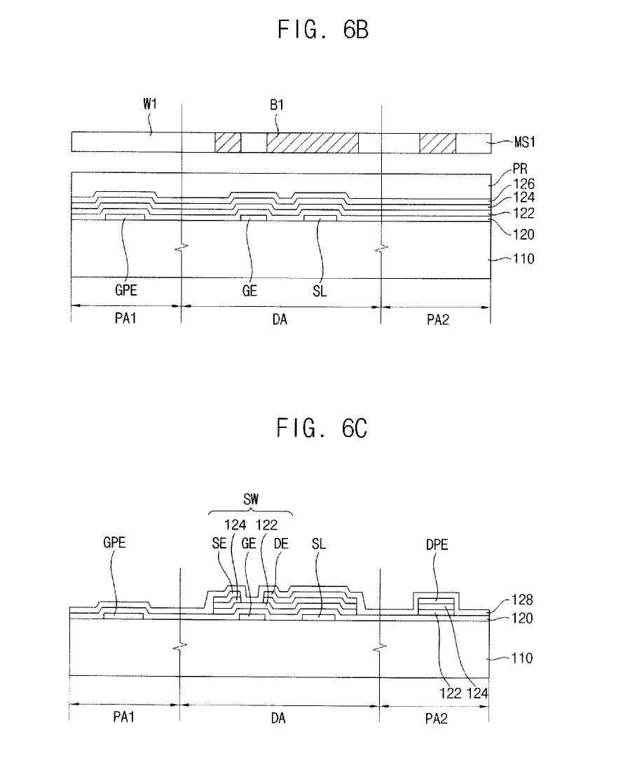

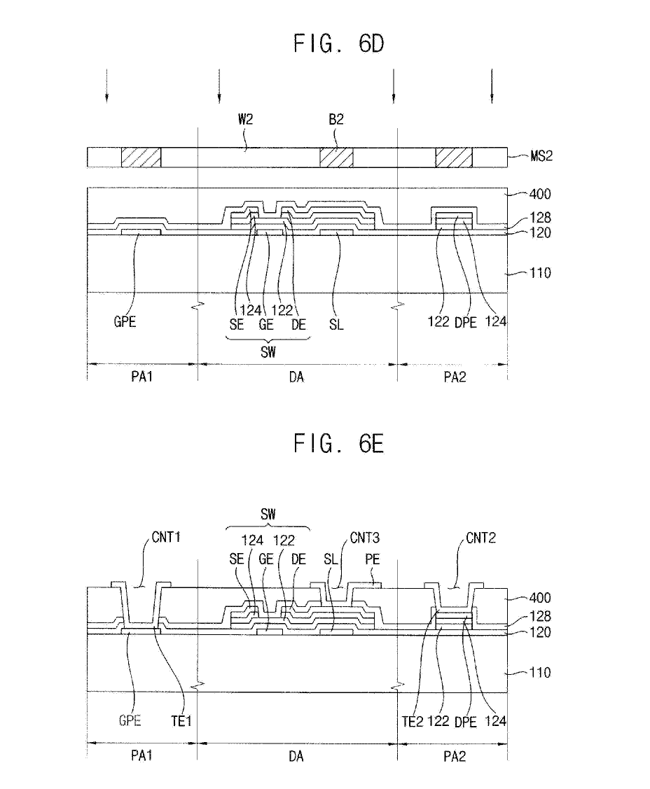

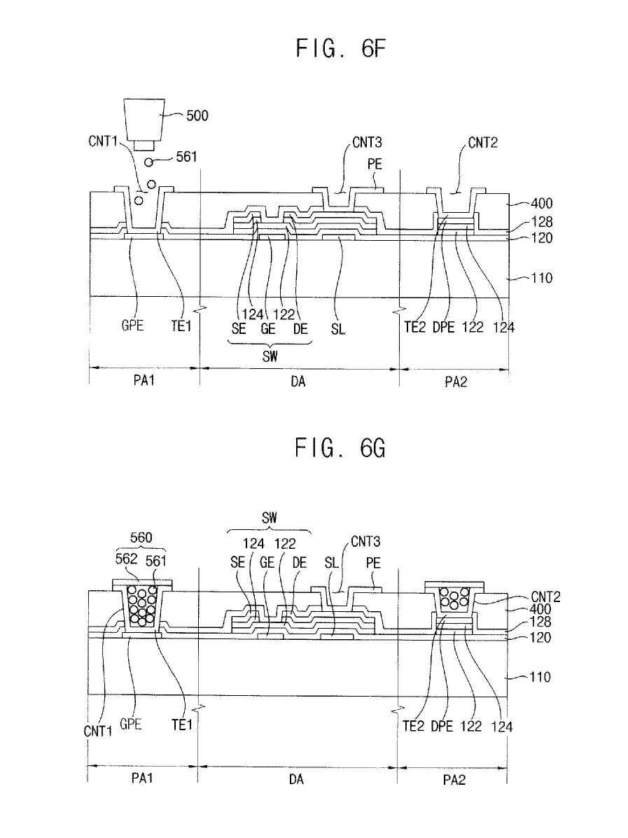

FIG. 6A, FIG. 6B, FIG. 6C, FIG. 6D, FIG. 6E, FIG. 6F, and FIG. 6G are cross-sectional views of the display substrate of FIG. 5 during various stages of its manufacture.

Referring to FIG. 6A, a gate pattern including a gate electrode GE, a storage line SL, and a gate pad electrode GPE are formed on the base substrate 110.

Referring to FIG. 6B, a first insulation layer 120, a semiconductor layer 122, an ohmic contact layer 124, a source metal layer 126, and a photoresist layer PR are formed on the base substrate 110 on which the gate pattern is formed to form a source pattern through a first mask MS1. The source pattern includes a drain electrode DE, a source electrode SE, and a data pad electrode DPE.

Referring to FIG. 6C and FIG. 6D, a second insulation layer 128 and an organic layer 400 are formed on the base substrate 110 on which the source pattern is formed. The organic layer 400 may include at least one of an organic film, a color filter, and a black matrix. Then, the organic layer 400 and the second insulation layer 128 is patterned by using a second mask MS2 to form the first to third contact holes CNT1, CNT2, and CNT3.

Referring to FIG. 6E, a transparent electrode layer (not shown) is formed on the base substrate 110 on which the first to third contact hole CNT1, CNT2, and CNT3 are formed. Then the transparent electrode layer is patterned to form the first transparent electrode TE1, the second transparent electrode TE2, and the pixel electrode PE in correspondence with the first to third contact holes CNT1, CNT2, and CNT3, respectively. A process for forming the first transparent electrode TE1 and the second transparent electrode TE2 may be omitted.

Referring to FIG. 6F, an inkjet printer 500 is located near the base substrate 110 on which the first transparent electrode TE1 and the second transparent electrode TE2 are formed, that is, a position corresponding to the first and second contact holes CNT1 and CNT2, to dispense conductive balls 561 within the first and second contact holes CNT1 and CNT2. The inkjet printer 500 may dispense the conductive balls 561 while adjusting the amount of the conductive balls 561 to accord with the depth and the size of the first and second contact holes CNT1 and CNT2.

Referring to FIG. 6G, the adhesive film 562 is disposed on the base substrate 110 on which the conductive balls 561 are disposed in the first and second contact holes CNT1 and CNT2 or the first and second transparent electrodes TE1 and TE2.

Thus, as shown in FIG. 5, the conductive balls 561 are dispensed, and then the adhesive film 562 is disposed on the first and second contact holes CNT1 and CNT2 having the conductive balls 561 filled therein. The driving part 300 is disposed on the base substrate 110 on which the adhesive film 562 is disposed. A connection terminal 310 of the driving part 300 contacts the adhesive film 562. Then, the conductive balls 561 and the adhesive film 562 are pressed at a temperature of about 170° C. to 200° C. to attach the driving part 300 to the first display substrate 100A. Thus, the driving part 300 electrically connects to the gate pad electrode GPE to provide a gate driving signal to the gate line GL through the gate pad electrode GPE.

According to the present exemplary embodiment, the organic layer 400 formed at the peripheral area PA is used as a partition, and the conductive balls 561 are disposed in the contact holes CNT1 and CNT2 corresponding to the pad electrodes GPE and DPE by the inkjet printer 500. The adhesive film 562 is disposed on the conductive balls 561 and attaches the driving part 300 to the pad electrodes GPE and DPE.

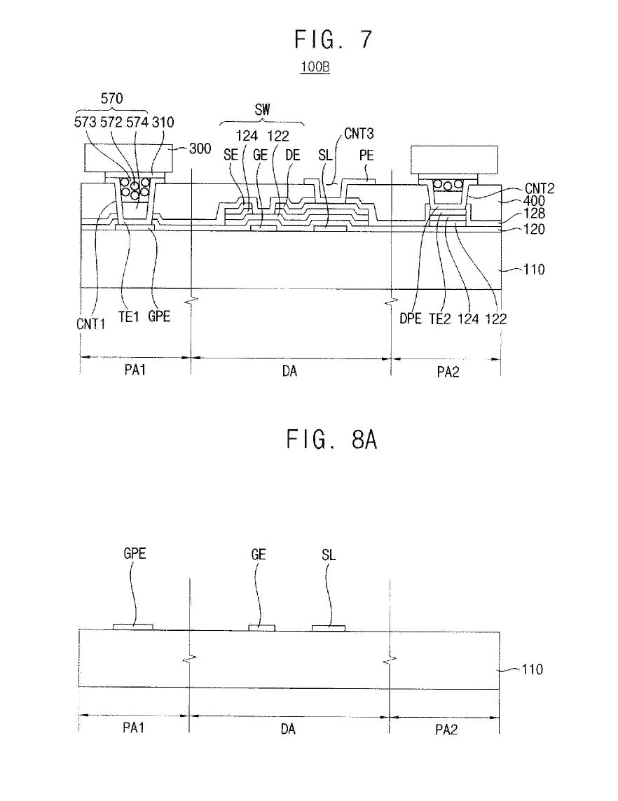

FIG. 7 is a cross-sectional view of the display panel according to another exemplary embodiment of the present invention.

The first display substrate 100B according to the present exemplary embodiment is substantially similar to the first display substrate 100 of FIG. 1 except for formation of the conductive member 570. Similar elements shown in FIG. 7 are labeled with the same reference characters as used above to describe the exemplary embodiment of the display substrate 100 in FIG. 1, and descriptions are simplified or not repeated.

Referring to FIG. 2 and FIG. 7, the first display substrate 100B includes a base substrate 110, an organic layer 400 and a second insulation layer 128 formed on the base substrate 110, a first contact hole CNT1 formed through the organic layer 400 and the first and second insulation layers 120 and 128, a second contact hole CNT2 formed through the organic layer 400 and the second insulation layer 128, a third contact hole CNT3 formed through the organic layer 400 and the second insulation layer 128, a pixel electrode PE, and a conductive member 570. The first display substrate 100B may further include a first transparent electrode TE1 and a second transparent electrode TE2.

The first contact hole CNT1 is formed through the organic layer 400 and the first and second insulation layers 120 and 128 corresponding to a first peripheral area PA1 of the base substrate 110 in correspondence with an area where a gate pad electrode GPE is formed. The second contact hole CNT2 is formed through the organic layer 400 and the second insulation layer 128 corresponding to a second peripheral area PA2 of the base substrate 110 in correspondence with an area where a data pad electrode DPE is formed. The third contact hole CNT3 is formed through the organic layer 400 and the second insulation layer 128 corresponding to a portion of a drain electrode DE in the display area DA.

The first transparent electrode TE1 is formed on an interior surface of the first contact hole CNT1 and along an upper surface of the gate pad electrode GPE to electrically connect to the gate pad electrode GPE. The second transparent electrode TE2 is formed on an interior surface of the second contact hole CNT2 and along an upper surface of the data pad electrode DPE and electrically connects to the data pad electrode DPE. The pixel electrode PE is formed on an interior surface of the third contact hole CNT3 and along an upper surface of a portion of the drain electrode DE and electrically connects to the drain electrode DE.

The conductive member 570 includes a mixture layer 571 and a conductive layer 574. The mixture layer 571 includes the conductive balls 572 and the adhesive 573. The mixture layer 571 and the conductive layer 574 are disposed within the first and second conductive holes CNT1 and CNT2. The mixture layer 571 may be disposed on the conductive layer 574 in the first and second contact holes CNT1 and CNT2. The conductive layer 574 may be formed in the first and second contact holes CNT1 and CNT2 with a given thickness. In order to decrease the step difference between an upper surface of the gate pad electrode GPE and the data pad electrode DPE with the upper surface of the organic layer 400, the conductive layer 574 is dispensed before the mixture layer 571 is dispensed in the first and second contact holes CNT1 and CNT2. The mixture layer 571 and the conductive layer 574 are disposed in correspondence with a position of the first and second contact holes CNT1 and CNT2 to be disposed in the first and second contact holes CNT1 and CNT2.

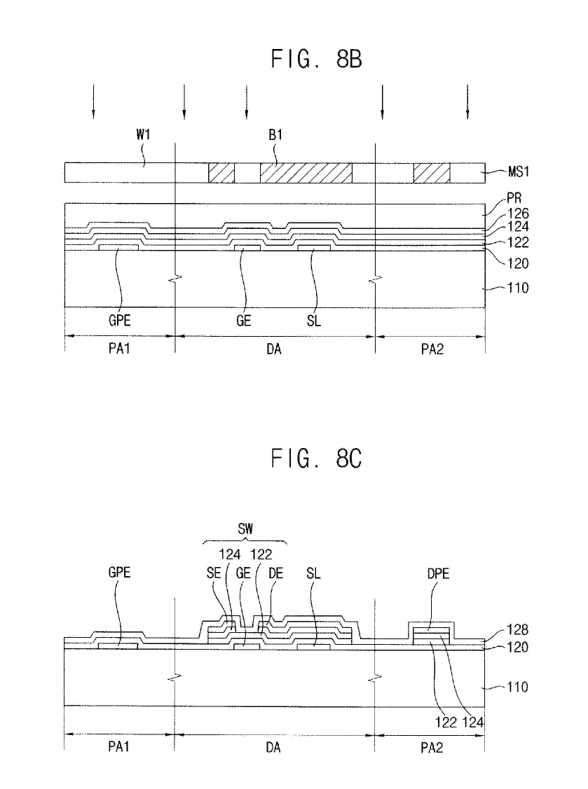

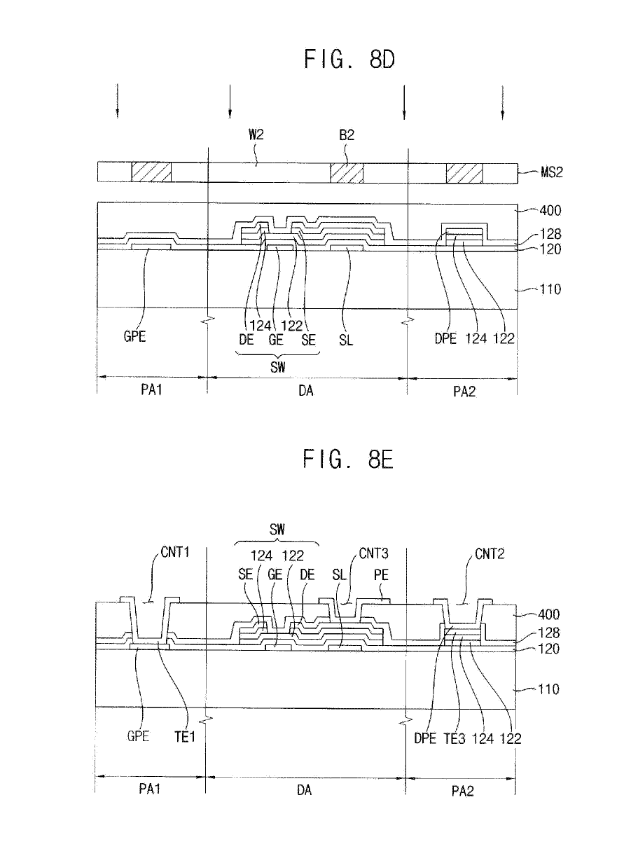

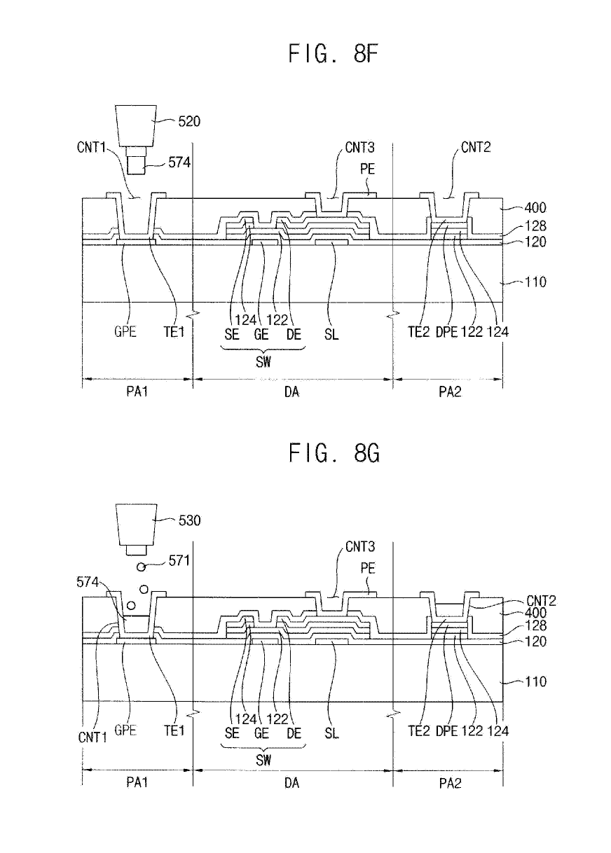

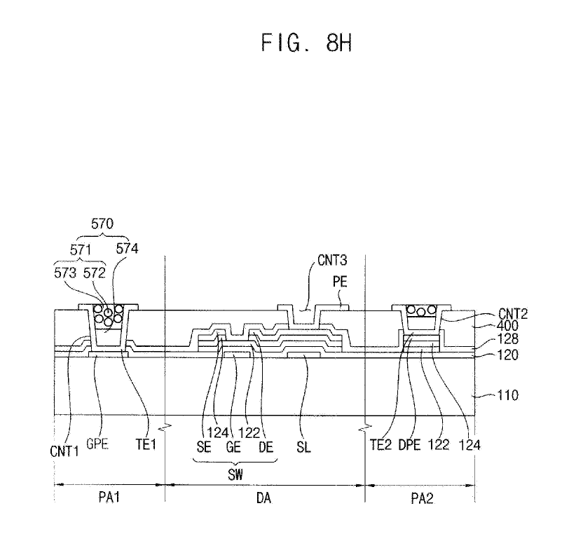

FIG. 8A, FIG. 8B, FIG. 8C, FIG. 8D, FIG. 8E, FIG. 8F, FIG. 8G, and FIG. 8H are cross-sectional views of the display substrate of FIG. 7 during various stages of its manufacture.

Referring to FIG. 8A, a gate pattern including a gate electrode GE, a storage line SL, and a gate pad electrode GPE are formed on the base substrate 110.

Referring to FIG. 8B, a first insulation layer 120, a semiconductor layer 122, an ohmic contact layer 124, a source metal layer 126, and a photoresist layer PR are formed on the base substrate 110 on which the gate pattern is formed, and then a source pattern is formed through a first mask MS1. The source pattern includes a drain electrode DE, a source electrode SE, and a data pad electrode DPE.

Referring to FIG. 8C and FIG. 8D, a second insulation layer 128 and an organic layer 400 are formed on the base substrate 110 on which the source pattern is formed. The organic layer 400 may include at least one of an organic film, a color filter, and a black matrix. Then, the organic layer 400 and the second insulation layer 128 is patterned by using a second mask MS2 to form the first to third contact holes CNT1, CNT2, and CNT3.

Referring to FIG. 8E, a transparent electrode layer (not shown) is formed on the base substrate 110 on which the first to third contact holes CNT1, CNT2, and CNT3 are formed, and then the transparent electrode layer is patterned to form the first transparent electrode TE1, the second transparent electrode TE2, and the pixel electrode PE in correspondence with the first to third contact holes CNT1, CNT2, and CNT3, respectively. A process for forming the first transparent electrode TE1 and the second transparent electrode TE2 may be omitted.

Referring to FIG. 8F, a first inkjet printer 520 is located near the base substrate 110 in a position where the first and second contact holes CNT1 and CNT2 are formed or where the first transparent electrode TE1 and the second transparent electrode TE2 are formed. That is, first inkjet printer 520 is disposed on a position corresponding to the first and second contact holes CNT1 and CNT2 to dispense a conductive material in the first and second contact holes CNT1 and CNT2. The conductive layer 574 is dispensed in the first and second contact holes CNT1 and CNT2 so that the conductive layer 574 may decrease a step difference between an upper surface of the gate and data pad electrodes GPE and DPE and an upper surface of the organic layer 400.

Here, since a step difference of the first contact hole CNT1 is larger than that of the second contact hole CNT2, a thickness of a conductive layer 574 formed within the first contact hole CNT1 may be greater than that of a conductive layer 574 formed within the second contact hole CNT2.

Referring to FIG. 8G and FIG. 8H, a second inkjet printer 530 is located near the base substrate 110 to dispense the mixture layer 571. That is, the second inkjet printer 530 is disposed on a position corresponding to the first and second contact holes CNT1 and CNT2 to dispense the mixture layer 571. The second inkjet printer 530 may dispense the mixture layer 571 by adjusting the amount of the mixture layer 571 to accord with the depth and size of the first and second contact holes CNT1 and CNT2 in which the first and second transparent electrodes TE1 and TE2 are formed, respectively.

Accordingly, as shown in FIG. 7, the driving part 300 is disposed on the base substrate 110 on which the conductive member 570 is disposed. A connection terminal 310 of the driving part 300 contacts with the conductive member 570. Then, the conductive member 570 is pressed at a temperature of about 170° C. to 200° C. to attach the driving part 300 to the first display substrate 100B. Thus, the driving part 300 electrically connects to the gate pad electrode GPE to provide a gate driving signal to the gate line GL through the gate pad electrode GPE.

According to the present exemplary embodiment, the organic layer 400 formed at the peripheral area PA partitions the conductive member 550. A conductive material is disposed within the contact hole corresponding to the pad electrodes GPE and DPE by the inkjet printer 520 to form the conductive layer 574 so a step difference between an upper surface of the pad electrodes GPE and DPE with the organic layer 400 may be decreased and have similar heights with respect to the base substrate 110.

As described above, according to the exemplary embodiments of the present invention, the organic layer formed at the peripheral area partitions the conductive member. A conductive material is dispensed in the contact hole corresponding to the pad electrode by the inkjet printer and electrically connects the pad electrodes and the driving parts. Therefore, press defects between the pad electrode and the driving part may be prevented.

Moreover, according to exemplary embodiments of the present invention, the organic layer remains so that a half-tone mask for removing the organic layer at the peripheral area is not required. Therefore, a manufacturing cost of the display panel may be decreased.

The foregoing is illustrative of the present invention and is not to be construed as limiting thereof. Although exemplary embodiments of the present invention have been described, it will be apparent to those skilled in the art that various modifications and variations can be made in the present invention without departing from the spirit or scope of the invention. Thus, it is intended that the present invention covers the modifications and variations of this invention provided they come within the scope of the appended claims and their equivalents.

Therefore, it is to be understood that the foregoing is illustrative of the present invention and is not to be construed as limited to the specific example embodiments disclosed, and modifications to the exemplary embodiments are intended to be included within the scope of the appended claims.

What is claimed is:

1. A display substrate, comprising:
a substrate comprising a display area and a peripheral area outside the display area;
a signal line disposed in the display area;
a pad electrode disposed on the peripheral area and electrically connected to the signal line;
an organic layer disposed on the substrate, the organic layer comprising a first contact hole exposing a portion of the pad electrode; and
a conductive member comprising a plurality of conductive balls disposed in the first contact hole and electrically connecting the pad electrode and a connection terminal of a driving part, the driving part to provide a driving signal to the signal line.

2. The display substrate of claim 1, wherein the conductive member further comprises an adhesive disposed in the first contact hole.

3. The display substrate of claim 2, wherein the conductive member further comprises a conductive material disposed in a lower portion of the first contact hole.

4. The display substrate of claim 1, further comprising an adhesive film disposed on the conductive member and attaching the driving part to the substrate.

5. The display substrate of claim 1, wherein the organic layer comprises at least one of an organic film, a color filter, and a black matrix.

6. The display substrate of claim 5, wherein the organic layer comprises the organic film, and the organic film is a negative-type organic film.

7. The display substrate of claim 1, wherein a height of the upper surface of the organic layer corresponding to the display area is substantially identical to a height of the upper surface of the organic layer corresponding to the peripheral area with respect to the substrate.

8. The display substrate of claim 1, further comprising a first transparent electrode disposed on the substrate corresponding to the first contact hole and electrically connected to a gate pad electrode,
wherein the signal line comprises a gate line arranged in a first direction, and the pad electrode comprises the gate pad electrode extending from the gate line.

9. The display substrate of claim 8, further comprising a second contact hole and a second transparent electrode,
wherein the signal line further comprises a data line arranged in a second direction crossing the first direction, the pad electrode comprises a data pad electrode electrically s connected to the data line, the second contact hole exposing the data pad electrode, and the second transparent electrode is disposed in the second contact hole.

10. A method of manufacturing a display substrate, the method comprising:
forming a signal line in a display area of a substrate;
forming a pad electrode in a peripheral area outside the display area, the pad electrode electrically connected to the signal line;
forming an organic layer on the substrate;
forming a contact hole corresponding to the pad electrode by removing a portion of the organic layer; and
forming a conductive member by disposing a conductive material comprising conductive balls in the contact hole,
wherein the conductive member electrically connects the pad electrode and a connection terminal of a driving part providing a driving signal to the signal line.

11. The method of claim 10, wherein the conductive material further comprises an adhesive material attaching the driving part to the substrate.

12. The method of claim 11, wherein forming the conductive member by disposing the conductive material comprises:
disposing the conductive material comprising the conductive balls and the adhesive material in the contact hole by a first inkjet printer.

13. The method of claim 12, wherein forming the conductive member by disposing the conductive material further comprises:
disposing a conductive layer by a second inkjet printer before disposing the conductive material by the first inkjet printer.

14. The method of claim 10, further comprising disposing an adhesive film on the conductive member.

15. The method of claim 10, wherein a height of the upper surface of the organic layer corresponding to the display area is substantially identical to a height of the upper surface of the organic layer corresponding to the peripheral area with respect to the substrate.

16. The method of claim 15, wherein the organic layer comprises at least one of an organic film, a color filter, and a black matrix.

17. The method of claim 16, wherein the organic layer comprises the organic film, and the organic film is a negative-type organic film.

18. The method of claim 10, further comprising:
forming a transparent electrode layer on the organic layer; and
patterning the transparent electrode layer to form a transparent electrode corresponding to the contact hole.

19. The method of claim 10, wherein forming the signal line and the pad electrode comprises:
forming a gate line arranged in a first direction on the display area, a gate electrode in the display area electrically connected to the gate line, and a gate pad electrode in the peripheral area electrically connected to the gate line;
forming a first insulation layer, a semiconductor layer, an ohmic contact layer, and a data metal layer on the substrate on which the gate line, the gate electrode, and the gate pad electrode are formed;
forming an active pattern in the display area by patterning the semiconductor layer and the ohmic contact layer;
forming a source electrode, a data line, and a drain electrode spaced apart from the source electrode in the display area and a data pad electrode electrically connected to the data line in the peripheral area by patterning the data metal layer to; and
forming a second insulation layer on the substrate, the organic layer being formed on the second insulation layer.
